(19) United States
(12) Patent Application Publication
(10) Pub. No.: US 2008/0204036 A1
(43) Pub. Date: Aug. 28, 2008

(54) Pulse-generating apparatus and a method for adjusting levels of pulses outputted from pulse-generating apparatus

(75) Inventors: Yukoh Iwasaki, Tokyo (JP); Yasushi Hashimoto, Tokyo (JP); Mio Murashima, Tokyo (JP)

Correspondence Address: Paul D. Greeley, Esq.;Ohlandt, Greeley, Ruggiero & Perle, L.L.P., 10th Floor, One Landmark Square, Stamford, CT, 06901-2682, US

(73) Assignee: AGILENT TECHNOLOGIES, INC.

(21) Appl. No.: 11/712,267

(22) Filed: Feb. 28, 2007

(51) Int. Cl. G01R 31/02

(52) U.S. Cl. 324/537; 324/765

(57) ABSTRACT

A pulse-generating apparatus, comprising a pulse source, an output terminal to which pulses from the pulse source are supplied, and a measuring device for measuring the level of a pulse that will be output from the output terminal at a pre-determined time position; a pulse-generating apparatus, further comprising a device for adjusting the level of the pulse that will be output at the pre-determined time position, based on at least the measured pulse level and the reference pulse level at the pre-determined time position; and a pulse-generating apparatus, wherein the pulse source generates pulses based on at least one parameter, and the adjusting device adjusts the level of the pulse that will be output by updating the parameter, changing the amount of amplification of the amplifier of the pulse source, or changing the amount of attenuation of the attenuator of the pulse source. The parameter may include at least one of the load impedance and the pulse level.

### BACKGROUND

1. Field of the Disclosure

The present disclosure pertains to a pulse-generating apparatus, and relates to a pulse-generating apparatus for supplying pulses to a component or apparatus whose impedance value is unknown or unclear.

2. Discussion of the Background Art

When the properties of a device under test (DUT) are measured, signals are applied to the device under test. When the properties of a semiconductor component, such as a field effect transistor (FET), an integrated circuit (IC), or a memory cell, are measured, pulses generated by a pulse generator are applied to the semiconductor component while the pulse level, etc. is changed, and the response to and the status change of the semiconductor as a result of these applied pulses are measured or monitored (refer to JP Unexamined Patent Publication (Kokai) 2004-64450 (pages 6 and 7, FIG. 1, FIG. 6), “Pulse Pattern and Data Generators,” PN: 5980-0489E, Oct. 24, 2006, Agilent Technologies, “Evaluation of Flash Memory Cells Application Note 4156-4,” PN: 5965-5657E, October, 2000, Agilent Technologies, and “Evaluation of the Surface State Using Charge Pumping Methods,” PN: 5964-2195 E, November, 2000, Agilent Technologies). The pulse level is the voltage level or the current level. An example of a pulse generator is the Pulse/Pattern Generator 81110 family of Agilent Technologies, Inc. By means of this pulse generator, the user can set the load impedance and the level of pulses output by the pulse generator when this load impedance is connected to the pulse generator. Moreover, a load impedance other than 50Ω or 1 kΩ can be set. As a result, a pulse having the desired level can be accurately output from the pulse generator even when the load impedance is not 50Ω or 1 kΩ.

However, there are many times when the impedance of a semiconductor component is unknown or unclear; in other words, the true impedance of a semiconductor component is not known with the desired accuracy. However, the impedance of a conventional semiconductor is much larger than 50Ω or 1 kΩ and is known to be on the order of 100 kΩ, for instance. The level of the pulses applied to a semiconductor component changes in accordance with the potential ratio, which is based on the signal source impedance of the pulse generator and the impedance of the semiconductor component. The signal source impedance of the pulse generator is 50Ω, and as described above, the impedance value of a conventional semiconductor component is much larger than 50Ω. Consequently, the potential ratio can be regarded as approximately 1, regardless of the impedance of the semiconductor component. Moreover, a conventional semiconductor component has a broader response level range than current semiconductor components; thus, conventional semiconductor components do not require a high accuracy of the pulse level. Therefore, in the past a semiconductor component of unknown or unclear impedance was connected to a pulse generator, the system was set at open-circuit impedance (for instance, approximately 999 kΩ) and the voltage level of the output pulse was set at the desired level. It was also possible to set the load impedance at 50Ω and to set the output pulse voltage level at half of the desired level. As a result, pulses of the desired level could be applied to a device under test with the desired accuracy.

However, a refinement of the design rules, a multiplexing of memory cell values, and similar advances have led to an increase in requirements for accuracy of the pulse level, such as a narrowing of the level range within which a semiconductor component responds. For instance, a level accuracy of 0.5% is required. In addition, the impedance of a semiconductor component is now smaller than the conventional impedance; for instance, it has become on the order of from 100Ω to 1 kΩ. Therefore, it is difficult to apply pulses of the desired level to a semiconductor component with the desired accuracy regardless of how high the impedance of the semiconductor component is.

By means of the present disclosure, the pulse level is corrected in accordance with the properties of the device under test before measurement pulses are applied to the device under test. In particular, the level of a pulse at a pre-determined time position is corrected so that it is brought to a pre-determined level. Correction is performed automatically or manually.

### SUMMARY OF THE DISCLOSURE

The present disclosure provides an apparatus and a method necessary for this correction. In essence, the first subject of the present disclosure is a pulse-generating apparatus, characterized in that it comprises a pulse source; an output terminal to which pulses from the pulse source are supplied; and a measuring device for measuring the level of a pulse that will be output from the output terminal at a pre-determined time position. The pre-determined time position points to a prescribed part of the pulse. The pre-determined time position may be a prescribed absolute time position or a relative time position in the pulse.

The second subject of the present disclosure is the pulse-generating apparatus of the first subject of the present disclosure, further characterized in that it comprises a device for adjusting the level of the pulse that will be output at the pre-determined time position, based on at least the measured pulse level and the reference pulse level at the pre-determined time position.

The third subject of the present disclosure is the pulse-generating apparatus of the second subject of the present disclosure, further characterized in that the pulse source generates pulses based on at least one parameter, and the adjusting device adjusts the level of the pulse that will be output by updating the parameter, changing the amount of amplification of the amplifier of the pulse source, or changing the amount of attenuation of the attenuator of the pulse source.

The fourth subject of the present disclosure is the pulse-generating apparatus according to the third subject of the present disclosure, further characterized in that the parameter is the load impedance or pulse level.

The fifth subject of the present disclosure is the pulse-generating apparatus of the first subject of the present disclosure, further characterized in that it comprises an arithmetic unit for calculating the load impedance based on the measured pulse level, the reference pulse level at the pre-determined time position, and the signal source impedance of the pulse source, and an output device for outputting the calculated load impedance.

The sixth subject of the present disclosure is the pulse-generating apparatus of the first subject of the present disclosure, further characterized in that it comprises an output device for outputting the measured pulse level.

The seventh subject of the present disclosure is a pulse-generating apparatus, characterized in that it comprises multiple pulse sources; multiple output terminals to which are individually supplied the pulses from the respective multiple pulse sources; a measuring device for measuring the level of at least one of the pulses output from each of the multiple output terminals at respective pre-determined time positions; and a device for adjusting, individually and in a pre-determined order, the levels of pulses at the respective pre-determined time positions that will be output, based on at least the relevant measured pulse levels and the corresponding reference values. The pre-determined time position points to a prescribed part of the pulse. The pre-determined time position may be a prescribed absolute time position or a relative time position in the pulse.

The eighth subject of the present disclosure is a semiconductor testing system comprising the pulse-generating apparatus of the first subject of the present disclosure.

The ninth subject of the present disclosure is a method for adjusting the level of the output pulses of a pulse-generating apparatus, characterized in that it comprises a step for connecting a device under test to the pulse-generating apparatus; a step for causing the pulse-generating apparatus to generate a pulse with the device under test connected to the pulse-generating apparatus; a step for measuring the level of the output pulse; and a step for adjusting the level of the output pulse at a pre-determined time position, based on at least the measured pulse level and the reference pulse level. The pre-determined time position points to a prescribed part of the pulse. The pre-determined time position may be a prescribed absolute time position or a relative time position in the pulse.

The tenth subject of the present disclosure is the method for adjusting the output pulse level of the ninth subject of the present disclosure, further characterized in that the level measurement step is for measuring the level of the pulse that will be output at a pre-determined time position, and the level adjustment step is for adjusting the level of the pulse that will be output at a pre-determined time position, based on at least the measured pulse level and the reference pulse level at a pre-determined time position.

The eleventh subject of the present disclosure is the method for adjusting the output pulse level of the ninth subject of the present disclosure, further characterized in that the pulse source generates a pulse based on at least one parameter, and the adjustment step is for adjusting the level of the pulse that will be output by updating the parameter, changing the amount of amplification of the amplifier of the pulse source, or changing the amount of attenuation of the attenuator of the pulse source.

The twelfth subject of the present disclosure is the method for adjusting the output pulse level of the eleventh subject of the present disclosure, further characterized in that the parameter is the load impedance or the pulse level.

The thirteenth subject of the present disclosure is a method for adjusting the level of the output pulse of a pulse-generating apparatus comprising multiple pulse sources and multiple output terminals to which pulses from each of the pulse sources are individually supplied, characterized in that it comprises a step for connecting each of the terminals of a device under test having multiple terminals that work together to each of the output terminals; a step for measuring the level of at least one of the pulses output from each of the multiple output terminals at respective pre-determined time positions; and a step for adjusting, individually and in a pre-determined order, the levels of the pulses at the respective pre-determined time positions that will be output, based on at least the relevant measured pulse levels and the corresponding reference values. The pre-determined time position points to a prescribed part of the pulse. The pre-determined time position may be a prescribed absolute time position or a relative time position in the pulse.

By means of the present disclosure, a pulse of the desired level is easily applied with the desired accuracy to a semiconductor component having unknown or unclear impedance.

### BRIEF DESCRIPTION OF THE DRAWINGS

FIG. 1 is a drawing showing the structure of semiconductor testing system 10, which is an embodiment of the present disclosure.

FIG. 2 is a drawing showing the structure of signal-generating apparatus 110.

FIG. 3 is a graph showing the output signals of signal-generating apparatus 110.

FIG. 4 is a graph showing the output signals of signal-generating apparatuses 110 and 140.

### DETAILED DESCRIPTION OF THE PREFERRED EMBODIMENT

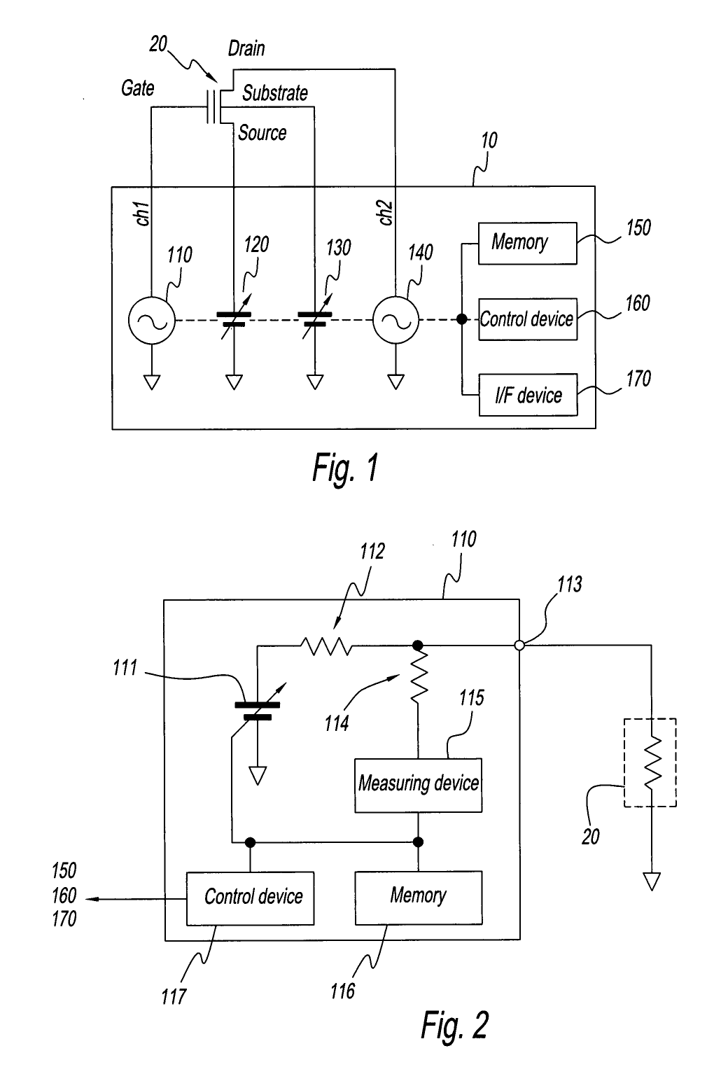

Embodiments of the present disclosure will now be described while referring to the drawings as needed. Refer to FIG. 1. FIG. 1 is a drawing showing the structure of a semiconductor testing system 10, which is an embodiment of the present disclosure. FIG. 1 shows the structure of a semiconductor testing system for evaluating a flash memory cell inside a TEG (Test Element Group) that is not illustrated, and, in particular, a simplified structure with emphasis on the flash memory cell write process. It should be noted that TEG is a device group for testing that is formed separately from the product on a semiconductor wafer in order to evaluate the quality of the semiconductor wafer. Hereafter the flash memory cell will be referred to simply as the memory cell. Refer to the above-mentioned “Evaluation of Flash Memory Cells Application No 4156-4” for the flash memory cell evaluation and the writing process. Writing in a memory cell is accomplished, for instance, by applying virtually simultaneously pulses of a pre-determined level (for instance, 12 V and 7 V) to the gate and drain of a memory cell, wherein a bias of a pre-determined level has been applied to the source and the substrate.

Semiconductor test system 10 comprises signal-generating apparatuses 110 and 140; voltage sources 120 and 130; a memory 150; a control device 160; and an interface device 170. The upside down triangles in the figure represent a common potential or a reference potential. The interface device is called an I/F device hereafter. Signal-generating devices 110 and 140 are devices for generating signals of any waveform, such as pulse signals, and bias of a constant level. Signal-generating apparatus 110 is electrically connected to the gate of a memory cell 20, which is the device under test, and feeds pulse signals, and the like to the gate of memory cell 20. Voltage source 120 is electrically connected to the source of memory cell 20, and supplies a bias voltage to the source of memory cell 20. Voltage source 130 is electrically connected to the substrate of memory cell 20 and supplies a bias voltage to the substrate of memory cell 20. Signal-generating apparatus 140 is electrically connected to the drain of memory cell 20 and supplies pulse signals, etc. to the drain of memory cell 20. Memory 150 is the device in which the data and the programs are stored. Memory 150 is, for instance, a semiconductor memory or a magnetic disk. Control device 160 is electrically connected to each of the structural elements inside semiconductor testing system 10 and is the device for controlling these structural elements. Moreover, control apparatus 160 operates by executing programs stored in memory 150. Control device 160 can also perform arithmetic processings. Control apparatus 160 is, for instance, a processor such as an MPU, or a computer comprising a processor. I/F device 170 is a device having an input function and an output function. I/F device 170 is, for instance, a display, printer, keyboard, mouse, LAN interface, or GP-IB interface.

Next, signal generating apparatus 110 will be described in further detail. Refer to FIG. 2 here. FIG. 2 is a drawing showing the structure of signal-generating apparatus 110. Signal-generating apparatus 110 comprises a voltage source 111, a resistor 112, an output terminal 113, a resistor 114, a measuring device 115, a memory 116, and a control apparatus 117. Voltage source 111 is a voltage source whose output voltage level is changed by external control. Voltage source 111 is electrically connected to the gate of memory cell 20 via resistor 112 and output terminal 113. Resistor 114 is connected close to the path between resistor 112 and output terminal 113 in such a way that a stub is not formed. Resistor 114 has a high enough resistance so that signals are not affected in the path between resistor 112 and output terminal 113. Measuring device 115 measures the voltage level of the pulse at output terminal 113 via resistor 114. Memory 116 is the device for storing data and programs. Control device 117 is electrically connected to each of the structural elements inside signal-generating apparatus 110, and is the apparatus for controlling these structural elements. Control device 117 can also perform arithmetic processings. Control device 117 is, for instance, a processor such as an MPU, or a computer having a processor.

Voltage source 111, resistor 112, control device 117, and memory 116 together operate as a signal source. Resistor 112 provides signal source impedance in this signal source. When signal-generating apparatus 110 generates pulse signals, signal-generating apparatus 110 operates as follows, for example: First, control device 117 consults the parameters relating to pulse generation wherein the parameters are pre-stored in memory 116, and control apparatus 117 controls voltage source 111 in such a way that the output voltage of voltage source 111 changes to form pulse shape based on the value of the consulted parameter. It should be noted that the parameters relating to pulse generation include, for example, pulse amplitude, pulse period, pulse width, pulse transition time (rise time, fall time), duty ratio, and impedance of the load to which the pulse apply. Although it goes without saying, the load is device under test 20. Moreover, when the pulse is a stepped pulse, the parameters relating to pulse generation include parameters necessary for defining any step shape, such as the starting voltage level and the ending voltage level. These parameters are set before the pulse is generated and stored in memory 116.

The voltage level of signals output from signal-generating apparatus 110 is determined by the potential ratio, which is based on the resistance of resistor 112 and the impedance at the gate of memory cell 20, and the output voltage level of voltage source 111. On the other hand, the voltage level that should be output by voltage source 111 is determined by the voltage level of the signals output from signal-generating apparatus 110 and the above-mentioned potential ratio. For instance, when the resistance of resistor 112 is Rs Ω, the impedance at the gate of memory cell 20 is Z Ω, and the voltage level that should be output from output terminal 113 is E, voltage source 111 is controlled in such a way that (E+E·Rs/Z) volts are output. The impedance at the gate of memory cell 20 is the load impedance. When the preset load impedance is different from the true impedance at the gate of memory cell 20, there is an error in the level of the pulses output from signal-generating apparatus 110. Signal-generating apparatus 110 has a function for correcting the output pulses so that this level error is a pre-determined value or less. The operation of signal-generating apparatus 110 during level correction is described below.

First, control device 117 consults to the values of parameters that include the load impedance. Moreover, control device 117 controls voltage source 111 in such a way that the output voltage of voltage source 111 changes to form pulse shape based on the values of the consulted parameters.

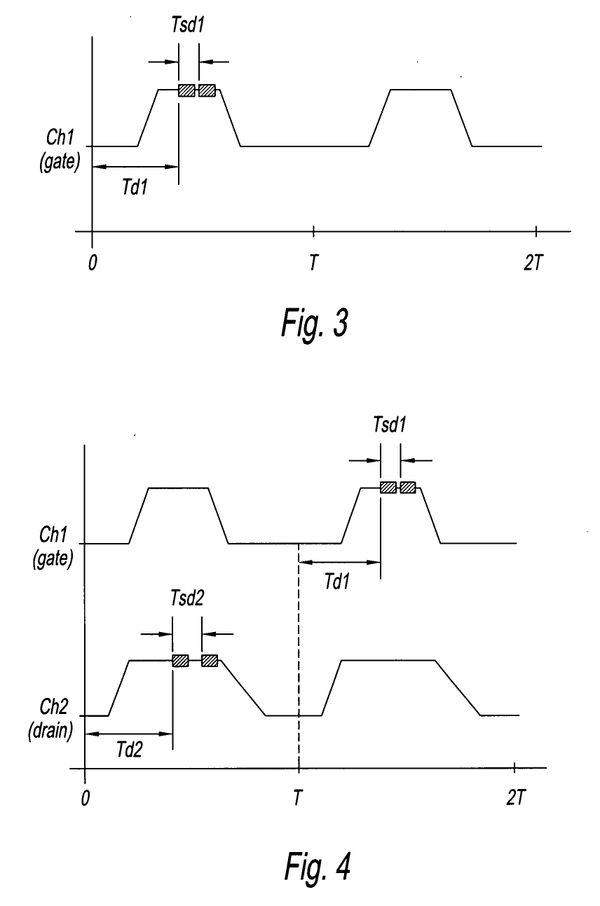

In this case, measuring device 115 is controlled by control apparatus 117 and measures the voltage level of the pulses produced by voltage source 111 at a pre-determined time position. The pre-determined time position points a prescribed part of the pulse. The time position is pre-stored in memory 116 and consulted by control apparatus 117. The measured pulse level (Lm) is stored in memory 116. When multiple levels are measured, each measurement is stored in memory 116. Moreover, the average of multiple measurements (La) is calculated by control apparatus 117 and this average is stored in memory 116. Refer to FIG. 2 and FIG. 3. FIG. 3 is a graph showing changes over time in a signal (ch1) output from output terminal 113 of signal-generating apparatus 110. The y-axis in FIG. 3 represents the level in terms of amplitude, and the x-axis represents time. T is the generation period of the pulse. Time zero, T, and 2T are the time points when pulse output is started. Td1 is the delay time from when pulse output starts until the first level measurement starts. Tsd1 is the measurement period when the level measurement is successive. For instance, the second level measurement starts at the point where there is a delay of (Td1+Tsd1) from the starting point of the pulse output measurement. The time position where the pulse level should be measured is designated by Td1 alone or a combination of Td1 and Tsd1. The boxes with the oblique lines in the figure represent the time when one measurement starts and ends. It goes without saying that the left end of the box is the time when measurements start. Each measurement is the pulse level when measurement starts.

Next, control apparatus 117 consults to the measured pulse level (Lm) and the reference pulse level (Lr) and calculates the first correction coefficient α=Lm·Rs/(Lr·Rs+Lr·RL−Lm·RL). It should be noted that when the level is measured multiple times, the average (La) is consulted as the Lm. Moreover, RL is the load impedance setting when the level is measured, in essence, the impedance setting at the gate of device under test 20. This setting is an estimate, an approximation, or an appropriate temporary value if the impedance at the gate of device under test 20 is unknown or unclear. Furthermore, reference pulse level (Lr) is the desired voltage level at the time position designated for pulse level measurement. The reference pulse level (Lr) is found by control apparatus 117 based on the value of parameters relating to pulse generation stored in memory 116. For example, the reference voltage level of a binary pulse at a pre-determined time position is calculated from the time from when pulse output starts up to the pre-determined time position, pulse delay time, pulse transition time, pulse width, and similar parameters.

Next, control apparatus 117 consults the settings of load impedance from memory apparatus 116. Control apparatus 117 finds the true impedance at the gate of memory cell 20 by multiplying the first correction coefficient α by the consulted setting.

Finally, control device 117 updates the setting of load impedance stored in memory 116. The true load impedance that has been determined is written over the existing load impedance. As a result, the voltage level of the pulse output from signal generating apparatus 110 at the pre-determined time position is adjusted and the voltage level of the output pulse is corrected such that it becomes a pre-determined level (Lr).

The parameters should be updated in such a way that the parameters consulted at the time of signal generation are newly determined parameters. Consequently, the following modification is possible. For example, it is possible to store the new values in memory 116 separately from the existing values rather than writing the new values over the existing values, so that the new values can be consulted when the pulse is generated.

Moreover, it is also possible to update the pulse level, which is a parameter stored in memory 116, rather than update the values of the load impedance. For instance, the pulse level can be the pulse amplitude (or the pulse height), the pulse offset level (or the base level), and similar parameters. Moreover, the term pulse level also includes the start level, the stop level, the step level, etc., which are parameters that define a step pulse. The values obtained by multiplying the second correction coefficient β=(Lr/Lm) by the existing values of these parameters can be written over the existing values. Moreover, the multiplication results can be stored in memory 116 separately from the existing values, so that the stored values can be consulted when the pulse is generated. As a result, the voltage level of pulse output from signal-generating apparatus 110 at the pre-determined time position is adjusted and the voltage level of the output pulse is corrected in such a way that it is brought to a pre-determined level (Lr).

When the signal source also has an amplifier or an attenuator, in essence, when an amplifier or attenuator is disposed between voltage source 111 and resistor 112, it is possible to change the amount of amplification of this amplifier or the amount of attenuation of this attenuator instead of updating the value of load impedance. The amount of amplification or the amount of attenuation is controlled by control apparatus 117 based on the second correction coefficient β. Specifically, control apparatus 117 controls the amplifier or attenuator in such a way that the amount of amplification or the amount of attenuation is multiplied by β or by 1/β. As a result, the voltage level of a pulse output from signal generator 110 at the pre-determined time position is adjusted and the voltage level of the output pulse is corrected in such a way that it becomes a pre-determined level (Lr).

Moreover, control apparatus 160 can operate in such a way that the measured pulse level, the average measured pulse level, or the true load impedance obtained during level correction can also be output to the operator of semiconductor testing system 10 through I/F apparatus 170. For instance, these values are displayed on a display. As a result, the operator can manually correct the output pulse level of signal-generating apparatus 110. It is also possible to correct the output pulse level of another signal-generating apparatus connected to memory cell 20 that is different from signal-generating apparatus 110. In this case, for instance, the true load impedance is set so that it is active for this other signal-generating apparatus.

Voltage source 111 can be replaced by a current source whose output current level is controlled by control apparatus 117. In this case, resistor 112 is connected in parallel with the current source. When compared to a voltage source, a current source is generally preferred for the generation of high-frequency signals or wide-band signals.

Measuring device 115 measures the signal level output by signal-generating apparatus 110 inside signal-generating apparatus 110. On the other hand, measuring device 115 can be changed so that it measures the signal level outside of signal-generating apparatus 110. For instance, resistor 114 can be electrically connected near the gate of memory cell 20 and measuring device 115 can measure the level of the signals output by signal-generating apparatus 110 via connected resistor 114. In this case, a terminal for level measurement to which measuring device 115 is connected directly or connected via resistor 114 should be newly disposed at signal-generating apparatus 110.

When levels are measured multiple times, in addition to finding the average of multiple measurements as described above, it is also possible to find the correction coefficient individually based on each measurement, average the resulting multiple correction coefficients, and use this average as the first correction coefficient or second correction coefficient. This averaging method is also appropriate when the level of each flat part of a pulse having two or more different levels is measured, and when the impedance of memory cell 20 is regarded as constant, regardless of the level of the pulse that is applied. On the other hand, when the impedance of memory cell 20 changes in accordance with the level of the applied pulse and is not regarded as constant, the first correction coefficient or the second correction coefficient should be found for each step of the pulse and the level of each step should be individually adjusted. In short, there are also cases in which the correction coefficients are used without being averaged. It should be noted that this method is used in cases in which pulses having two or more steps of different levels are applied to a multiple-valued memory cell.

The above is a detailed description relating to the structure and operation of signal generating apparatus 110 as well as modified embodiments. Signal-generating apparatus 140 has the same structure as signal-generating apparatus 110, operates in the same way as signal-generating apparatus 110, and can have the same modifications as signal-generating apparatus 110. Therefore, a detailed description relating to signal-generating apparatus 140 is not given.

If the loads connected to each of signal-generating apparatuses 110 and 140, in essence, the gate and drain of memory cell 20, operated independently, the level correction of both signal-generating apparatuses 110 and 140 could be individually executed as needed. However, the gate and drain of memory cell 20 work together; therefore, the level correction of signal-generating apparatuses 110 and 140 should be executed in a pre-determined order for each output pulse. Refer to FIGS. 1 and 4. FIG. 4 is a graph showing the changes over time in the signals (ch1) output from signal-generating apparatus 110, and the changes over time in the signals (ch2) output from signal-generating apparatus 140. The y-axis in FIG. 4 represents the level in terms of amplitude, while the x-axis represents time. T is the pulse generation period. Times 0, T, and 2T each represent the reference point where the pulse output begins. Td1 and Td2 are the delay times from when the pulse output starts until the first level measurement starts. Moreover, Tsd1 and Tsd2 are the measurement periods when the level measurement is successive. The time position where the pulse level should be measured is designated using at least one of Td1, Td2, Tsd1, and Tsd2. By the way, when compared to the gate of memory cell 20, the drain of memory cell 20 is more sensitive to changes in applied voltage levels and tends to affect the properties of memory cell 20 overall, or the properties at the other terminal. Therefore, the level correction is first executed at signal-generating apparatus 140 and then the level correction is executed at signal-generating apparatus 110. In this case, semiconductor testing system 10 operates as described below.

First, control device 160 controls voltage source 120 and voltage source 130 in such a way that a pre-determined bias voltage is generated by voltage source 120 and voltage source 130. Moreover, control device 160 sets the parameters relating to the pulses that should be generated for both signal-generating apparatuses 110 and 140. It should be noted that it is preferred that the settings, etc. for the load impedance are given as approximate values that are close to the true values. Moreover, parameters relating to measurements conducted at the time of correction (time position when measurement starts, measurement interval, number of measurements, and similar parameters) are similarly set by control device 160. These pre-determined bias voltages, parameters relating to pulse and parameters relating to measurement are values that are previously set by the operator and stored in memory 150 using I/F device 170. Control device 160 consults the stored parameters. Moreover, each of the values previously set for signal-generating apparatuses 110 and 140 is stored in their respective memories. Next, control device 160 controls signal-generating apparatuses 110 and 140 in such a way that signal-generating apparatus 110 generates the pulse and signal-generating apparatus 140 executes the pulse correction, and then control device 160 controls signal-generating apparatuses 110 and 140 in such a way that signal-generating apparatus 140 generates the pulse and signal-generating apparatus 110 executes the pulse correction. The level correction for signal-generating apparatuses 110 and 140 is repeated in a pre-determined order until pre-determined conditions are satisfied. In short, the level correction of signal-generating apparatus 140, the level correction of signal-generating apparatus 110, [and again] the level correction of signal-generating apparatus 140, the level correction of signal-generating apparatus 110, etc. is repeated. The phrase “pre-determined conditions” here means that the measured pulse level (or average) output by each signal-generating apparatus becomes a pre-determined level with a pre-determined accuracy. The level correction is executed as described above.

By means of semiconductor testing system 10, signal-generating apparatuses 110 and 140 are individual apparatuses, but they can be replaced with a signal-generating device that comprises these signal-generating apparatuses as one single unit. In this case, several structural elements of the signal-generating apparatuses may be shared. For instance, the switches might be used with the measuring devices of the signal-generating apparatus for the successive measurement of voltage levels at multiple points.

The above description has described embodiments by which signal-generating apparatus 110 outputs a pre-determined voltage level. Persons skilled in the art will be able to envision the present disclosure as being effective for an embodiment wherein signal-generating apparatus 110 outputs a pre-determined current level. For instance, when the output current level of signal-generating apparatus 110 in FIG. 2 is adjusted to become a pre-determined reference value (Sr), the load impedance setting should be multiplied by the correction coefficient γ=(Rs·Sr+RL·Sr−Rs·Sm)/(Sm·RL) when the level is measured. Sr here is the reference pulse level, and is a pre-determined current level at the time position designated for pulse level measurement. Moreover, Sm is the pulse current level measured at the pre-determined time position.

The signal generation and correction by the signal-generating apparatus as described in the present specification is not limited to pulses and can be applied to other types and other forms of signals.

What is claimed is:

1. A pulse-generating apparatus which comprises:
a pulse source,
an output terminal to which pulses from the pulse source are supplied, and
a measuring device for measuring the level of a pulse that will be output from the output terminal at a pre-determined time position.

2. The pulse-generating apparatus according to claim 1, further comprising a device for adjusting the level of the pulse that will be output at the pre-determined time position, based on at least the measured pulse level and the reference pulse level at the pre-determined time position.

3. The pulse-generating apparatus according to claim 2, wherein said pulse source generates pulses based on at least one parameter, and the adjusting device adjusts the level of the pulse that will be output by updating the parameter, changing the amount of amplification of the amplifier of the pulse source, or changing the amount of attenuation of the attenuator of the pulse source.

4. The pulse-generating apparatus according to claim 3, wherein the parameter is the load impedance or pulse level.

5. The pulse-generating apparatus according to claim 1, further comprising: an arithmetic unit for calculating the load impedance based on the measured pulse level, the reference pulse level at the pre-determined time position, and the signal source impedance of the pulse source, and an output device for outputting the calculated load impedance.

6. The pulse-generating apparatus according to claim 1, further comprising an output device for outputting the measured pulse level.

7. A pulse-generating apparatus which comprises:
multiple pulse sources,
multiple output terminals to which are individually supplied the pulses from the respective multiple pulse sources,
a measuring device for measuring the level of at least one of the pulses output from each of the multiple output terminals at respective pre-determined time positions, and
a device for adjusting, individually and in a pre-determined order, the levels of pulses at the respective time positions that will be output, based on at least the relevant measured pulse levels and the corresponding reference values.

8. A semiconductor testing system, comprising a pulse-generating apparatus which comprises:
a pulse source,
an output terminal to which pulses from the pulse source are supplied, and
a measuring device for measuring the level of a pulse that will be output from the output terminal at a pre-determined time position.

9. A method for adjusting the level of the output pulses of a pulse-generating apparatus, said method for adjusting the output pulse level comprising:
connecting a device under test to the pulse-generating apparatus;
causing the pulse-generating apparatus to generate a pulse with the device under test connected to the pulse-generating apparatus;
measuring the level of the output pulse; and
adjusting the level of the output pulse at a pre-determined time position, based on at least the measured pulse level and the reference pulse level.

10. The method for adjusting the output pulse level according to claim 9, wherein the level measurement step is for measuring the level of the pulse that will be output at a pre-determined time position, and the level adjustment step is for adjusting the level of the pulse that will be output at a pre-determined time position, based on at least the measured pulse level and the reference pulse level at a pre-determined time position.

11. The method for adjusting the output pulse level according to claim 9, wherein the pulse source generates a pulse based on at least one parameter and the adjustment step is for adjusting the level of the pulse that will be output by updating the parameter, changing the amount of amplification of the amplifier of the pulse source, or changing the amount of attenuation of the attenuator of the pulse source.

12. The method for adjusting the output pulse level according to claim 11, wherein the parameter is the load impedance or the pulse level.

13. A method for adjusting the level of the output pulse of a pulse-generating apparatus comprising multiple pulse sources and multiple output terminals to which pulses from each of the pulse sources are individually supplied, said method for adjusting the output pulse level comprises:
connecting each of the terminals of a device under test having multiple terminals that work together to each of the output terminals;
measuring the level of at least one of the pulses output from each of the multiple output terminals at respective pre-determined time positions; and
adjusting, individually and in a pre-determined order, the levels of the pulses at the respective pre-determined positions that will be output, based on at least the relevant measured pulse levels and the corresponding reference values.
